(19) United States
(12) Patent Application Publication
(10) Pub. No.: US 2026/0297806 A1
(43) Pub. Date: Oct. 1, 2026

(54) METHOD FOR MANUFACTURING A PLURALITY OF POLYCRYSTALLINE SILICON CARBIDE SUBSTRATES

(71) Applicant: Soitec, BERNIN (FR)

(72) Inventors: Hugo Biard, BERNIN (FR); Valentine Chagneux, BERNIN (FR); Thierry Boudet, BERNIN (FR); Christophe Figuet, BERNIN (FR); Mélanie Lagrange, BERNIN (FR)

(21) Appl. No.: 19/480,647

(22) PCT Filed: May 10, 2024
(86) PCT No.: PCT/EP2024/062906

§ 371 Date: Oct. 31, 2025

(30) Foreign Application Priority Data
May 12, 2023 (FR) 2304741

(51) Int. Cl. C30B 28/14; C30B 29/36; C30B 33/08

(52) U.S. Cl. CPC C30B 28/14; C30B 29/36; C30B 33/08

(57) ABSTRACT

A method of fabricating a plurality of polycrystalline silicon carbide substrates includes: forming a multilayer structure by alternating deposition of a plurality of polycrystalline silicon carbide layers and a plurality of separating layers on at least one face of a temporary support substrate; and detaching each polycrystalline silicon layer from the multilayer structure by removing the temporary substrate and each separating layer to form a respective polycrystalline silicon substrate.

### CROSS-REFERENCE TO RELATED APPLICATIONS

This application is a national phase entry under 35 U.S.C. § 371 of International Patent Application PCT/EP2024/062906, filed May 10, 2024, designating the United States of America and published as International Patent Publication WO 2024/235838 A1 on Nov. 21, 2024, which claims the benefit under Article 8 of the Patent Cooperation Treaty of French Patent Application Serial No. FR2304741, filed May 12, 2023.

### TECHNICAL FIELD

The present disclosure relates generally to the field of the fabrication of silicon carbide substrates for the formation of electronic components. More particularly, it proposes a process for the simultaneous fabrication of a plurality of polycrystalline silicon carbide substrates.

### BACKGROUND

For the formation of electronic components, use is often made of polycrystalline silicon carbide (p-SiC) substrates comprising at their surface a layer of a monocrystalline material such as monocrystalline silicon carbide (m-SiC), gallium nitride (GaN), gallium oxide (Ga₂O₃) or diamond.

In order to ensure good mechanical and electrical contact between the support substrate and the monocrystalline layer, the p-SiC base substrate must have a homogeneous crystal quality and a smooth surface. Typically, the preparation of such a base substrate comprises the chemical vapor deposition of a thick layer of p-SiC on a temporary substrate, for example, a graphite substrate, followed by removal of the temporary substrate to isolate the thick p-SiC layer.

Significant thicknesses are then removed from the p-SiC layer in order to retain just a thin portion having a suitable crystal quality for the deposition of an m-SiC layer. Thus, the thick p-SiC layer typically has an initial thickness of between 900 and 3000 μm. After removal of the portions of inferior crystal quality, a thickness of typically around 350 μm is retained, which has a suitable crystal quality for receiving an m-SiC layer.

The p-SiC deposited by CVD is very hard and difficult to cut. Due to the grains of the polycrystalline structure, there is a high risk of breakage during cutting. Moreover, each cutting hardens a surface zone of the wafers, which must be removed subsequently by grinding and/or polishing. This entails a significant loss of material. For this reason, it is difficult to prepare a block of p-SiC having a thickness equivalent to a plurality of base substrates and to cut, from such a block, a plurality of substrates. Each base substrate is therefore fabricated individually.

This process is long and laborious. It also involves a high consumption of p-SiC, which is removed before the deposition of the m-SiC layer and is therefore not used in the substrate to be fabricated.

### BRIEF SUMMARY

One aim of the present disclosure is to provide a process for simultaneously fabricating a plurality of polycrystalline silicon carbide substrates, which is more economical than the existing processes.

To this end, the present disclosure proposes a process for fabricating a plurality of polycrystalline silicon carbide substrates, the process comprising the following steps:
forming a multilayer structure by alternating deposition of a plurality of polycrystalline silicon carbide layers and a plurality of separating layers on at least one face of a temporary support substrate, and
detaching each polycrystalline silicon layer from the multilayer structure by removing the temporary substrate and each separating layer to form a respective polycrystalline silicon substrate.

The use of the separating layers allows easy separation of the polycrystalline silicon carbide layers without the risk of breakage.

In certain embodiments, the deposition of each polycrystalline silicon carbide layer and of each separating layer is effected simultaneously over the entire outer surface of the temporary support substrate and/or of the respective underlying layer.

The deposition over the periphery of the substrate and thus the use of the temporary support substrate on its two free faces make it possible to increase the yield of the process.

The process then additionally comprises a step of removing the edges of the multilayer structure after the deposition of the final polycrystalline silicon carbide layer, so as to expose an edge of the temporary support substrate.

In a particularly advantageous manner, the temporary support substrate may be made of graphite.

Particularly advantageously, each separating layer is made of carbon, of graphite, of silicon or of silicon nitride (Si₃N₄).

In certain embodiments, the removal of the temporary support substrate is carried out by combustion under a stream of oxygen at a temperature of between 700 and 1100° C., preferably between 800° C. and 900° C.

In certain embodiments, the removal of each separating layer is carried out by combustion.

In other embodiments, the removal of each separating layer is carried out by sawing or by chemical etching or by laser cutting.

In certain embodiments, the thickness of the temporary support substrate is between 1 and 15 mm.

In certain embodiments, the thickness of each polycrystalline silicon carbide layer is between 300 and 1200 μm.

In certain embodiments, the thickness of each separating layer is between 1 and 50 μm.

In other embodiments, the thickness of each separating layer is between 1 and 500 nm.

In certain embodiments, the thickness of each separating layer increases with the distance from the temporary support substrate.

Another subject of the present disclosure relates to a process for fabricating a plurality of substrates each comprising a polycrystalline silicon carbide base substrate and a layer of a monocrystalline material, the process comprising in succession:
implementing the process as described above for fabricating each polycrystalline silicon carbide substrate,
smoothing a front face of each polycrystalline silicon carbide base substrate, and
transferring a layer of a monocrystalline material to the front face of each polycrystalline silicon carbide base substrate.

In certain embodiments, transferring the monocrystalline material layer comprises the following steps:
forming a weakened zone by implantation of atomic species into a donor substrate made of a monocrystalline material, to delimit a monocrystalline material layer to be transferred,
bonding the donor substrate to the front face of the base substrate, and
detaching the donor substrate along the weakened zone so as to transfer the layer of the monocrystalline material to the base substrate.

Another subject of the present disclosure relates to an intermediate substrate, comprising:
a temporary support substrate, and
on at least one face of the temporary substrate, an alternating stack of a plurality of polycrystalline silicon carbide layers and separating layers.

Advantageously, the temporary support substrate is made of graphite.

Preferably, each separating layer is made of carbon, of graphite, of silicon or of silicon nitride.

### BRIEF DESCRIPTION OF THE DRAWINGS

Other features and advantages of the present disclosure will become apparent from the following detailed description, with reference to the appended drawings, in which:

FIG. 1 illustrates a temporary support substrate.

FIG. 2 illustrates a temporary support substrate comprising a first p-SiC layer.

FIG. 3 illustrates a temporary support substrate comprising a first p-SiC layer and a first separating layer.

FIG. 4 is a schematic view of a temporary support substrate comprising a plurality of p-SiC layers and a plurality of separating layers.

FIG. 5 is a schematic view of a temporary support substrate after edge polishing.

FIG. 6 illustrates a plurality of polycrystalline silicon carbide substrates.

FIG. 7 illustrates the formation of a weakened zone in a donor substrate.

FIG. 8 illustrates the transfer of a monocrystalline layer to a p-SiC base substrate.

FIG. 9 illustrates a substrate comprising a p-SiC base substrate and a monocrystalline layer on its front face.

### DETAILED DESCRIPTION

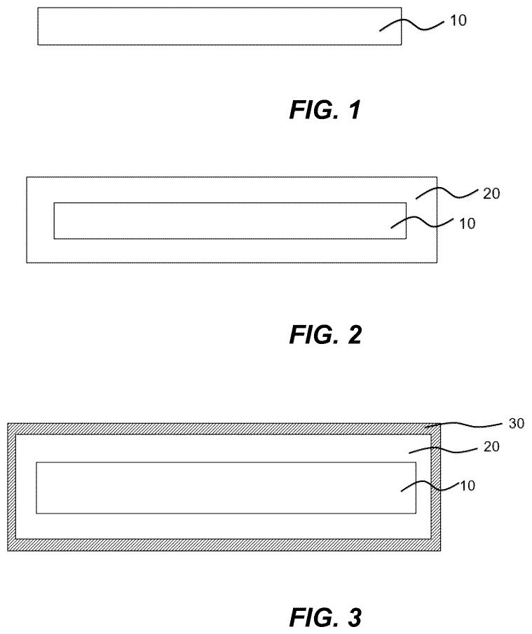

FIGS. 1 to 6 illustrate the steps of the process for fabricating a plurality of silicon carbide substrates. The substrates are deposited successively on a temporary support substrate and separated by separating layers. A multilayer substrate is thus fabricated, which is subsequently separated into a plurality of individual p-SiC substrates.

### Temporary Support Substrate

With reference to FIG. 1, to begin with the temporary support substrate 10 is provided. Preferably, the temporary support substrate 10 is made of graphite. The temporary support substrate has two main parallel faces: a front face and a rear face.

Graphite has a coefficient of thermal expansion close to that of silicon carbide. For this reason, it is particularly suitable as temporary support substrate material for the fabrication of a substrate involving high-temperature steps such as depositions by CVD. Moreover, graphite is easy to remove in a later step of the process, for example, by combustion or by chemical attack.

The temporary support substrate has a sufficient thickness to be self-supporting and sufficiently stable for the deposition of several successive layers without significant deformation of the temporary support substrate. Preferably, the thickness of the temporary support substrate is between 1 and 15 mm. The temporary support substrate has a sufficiently smooth surface to enable the uniform deposition of several successive layers without significant deformation of their surface. The temporary support substrate has a coefficient of thermal expansion close to that of the p-SiC in order to avoid delaminations and the breakage of the substrate during high-temperature treatments (a phenomenon denoted by the term “cracking”).

### Deposition of the Layers

With reference to FIG. 2, a first layer 20 of polycrystalline silicon carbide (p-SiC) is deposited on the temporary support substrate 10. The p-SiC can have any electrical resistivity that is suitable for the intended use. According to preferred embodiments, the p-SiC is doped, for example, with nitrogen or with phosphorus. In other embodiments, the p-SiC has a high electrical resistivity.

The p-SiC is preferably deposited in the form of micrometric grains having a homogeneous structure and size over the entire thickness of the layer to be deposited. The term “micrometric” is understood in the present text to mean a grain size of greater than 1 μm in a plane parallel to the front face of the temporary support substrate, that is to say perpendicular to the growth direction of the p-SiC layer. Preferably, the size of the grains within this plane is less than 100 μm. Particularly advantageously, the grains have a size of between 1 μm and 50 μm in a plane parallel to the front face of the temporary substrate. The grains are typically elongate along the growth direction of the p-SiC layer, such that they typically have a size in the growth direction that is greater than the size in a plane perpendicular to the growth direction. Preferably, the p-SiC grains have a size of less than 250 μm in the growth direction. Particularly advantageously, the size of the grains in the growth direction is between 1 μm and 100 μm.

The p-SiC layer 20 is preferably deposited by a CVD deposition process. Illustratively and in a non-limiting manner, the deposition of the p-SiC layer is carried out at a temperature of between 1100 and 1500° C. Typically, the temporary support substrate is placed within a deposition chamber and the deposition is carried out such that the p-SiC layer extends over the entire surface of the temporary support substrate, including its circumference. In certain embodiments, the p-SiC layer is deposited on the front face and the rear face of the temporary support substrate. In other embodiments, the p-SiC layer may be deposited on just one face of the temporary support substrate. In both cases, p-SiC may be deposited on the sides of the support substrate.

Alternatively, the p-SiC may be deposited by physical vapor deposition (PVD) or by physical vapor transport (PVT). The p-SiC may also be deposited by liquid-phase CVD or atmospheric-pressure CVD, by high-temperature CVD or by direct liquid injection CVD. The p-SiC may also be deposited from trichlorosiloxane.

The thickness of the p-SiC layer corresponds to the thickness of the p-SiC substrate to be fabricated and depends on the final use of the p-SiC substrate. The thickness of such a substrate is often chosen according to the dimensions of the substrate in order to provide a self-supporting and mechanically stable substrate. For example, a p-SiC substrate having a diameter of 150 mm (6″) typically has a thickness of greater than 50 μm, more advantageously of greater than 100 μm, in order to be self-supporting. For the fabrication of such a substrate, a first layer 20 having a thickness of between 300 μm and 900 μm, preferably between 360 μm and 900 μm, is typically deposited. A p-SiC substrate having a diameter of 200 mm (8″) typically has a thickness of between 510 and 1200 μm. For the fabrication of such a substrate, a first layer 20 having a minimum thickness of 510 μm is typically deposited.

For subsequent layers, the thickness of each p-SiC layer is, for example, greater than or equal to 500 μm for a substrate of 150 mm diameter, and greater than or equal to 650 μm for a substrate of 200 mm diameter.

The maximum thickness of the p-SiC layers may be 900 μm for a substrate of 150 mm diameter, and 1.2 mm for a substrate of 200 mm diameter.

Polishing of the p-SiC substrate can thus be carried out in order to optimize its surface quality and attain the final thickness.

With reference to FIG. 3, a separating layer 30 is then deposited on the p-SiC layer 20. The separating layer 30 may be made of carbon, graphite, silicon, silicon nitride, titanium nitride, or another material that can easily be removed from a p-SiC layer. Preferably, the deposition of the separating layer 30 is carried out in the same deposition chamber as the deposition of the p-SiC layer 20. It is therefore not necessary to remove the substrate from the chamber between successive depositions. This thus avoids handling of the substrate and the risk of contaminating the interface between the p-SiC layer 20 and the separating layer 30. Opening and possible contamination of the deposition chamber is also avoided. The thickness of the separating layer 30 may be nanometric, for example, of between 1 and 500 nm, or micrometric, for example, of between 1 and 50 μm.

The separation layer may be deposited over the whole surface of the p-SiC layer. In certain embodiments, the separating layer is deposited solely on the front face of the temporary support substrate comprising the p-SiC layer on its front face, or on the front face and the rear face of a temporary support substrate 10 comprising a p-SiC layer on its front face and on its rear face.

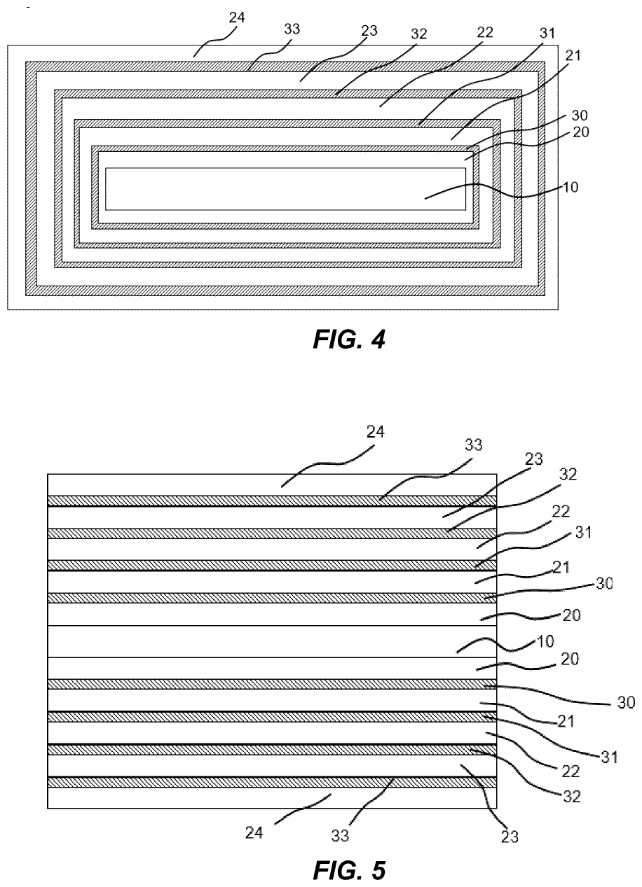

With reference to FIG. 4, p-SiC layers 20, 21, 22, 23, 24 and separating layers 30, 31, 32, 33 are subsequently deposited in succession in order to fabricate a multilayer structure. The depositions of the two types of layers are alternated in order to obtain a structure in which the p-SiC layers and the separating layers follow one another in succession. A separating layer is always arranged between two successive p-SiC layers. Illustratively and in a non-limiting manner, the last layer 24 deposited is a p-SiC layer. Thus, for a multilayer structure comprising n p-SiC layers, n—1 separating layers are deposited, with n being an integer. Typically, a number n of p-SiC layers of between 2 and 20, preferably between 5 and 15, are deposited.

Typically, each p-SiC layer and each separating layer are deposited over the entire surface of the respective underlying layer. In this way it is possible to produce a multilayer structure solely on a front face of the temporary support substrate. Alternatively, it is possible to produce a multilayer structure simultaneously on the front face and on the rear face of the temporary support substrate. In a preferred embodiment, the temporary support substrate is installed in a deposition chamber and each layer is deposited over all of the surface of the temporary support substrate or, respectively, over all of the surface of the respective underlying layer.

The simultaneous use of the front face and the rear face of the temporary support substrate makes it possible to increase the yield of the process by doubling the number of layers formed by a given deposition step.

Typically, during a simultaneous deposition on both faces of a substrate, material will also be deposited on the edges.

During the deposition of the two types of layers, namely the p-SiC layers and the separating layers, in a single chamber, manipulation of the temporary support substrate is not necessary before finalization of the multilayer structures. Moreover, transfer operations for introducing and removing the substrate to and from a deposition chamber are avoided, which avoids contamination of the chamber and of the interfaces between the respective layers.

The thickness of the separating layer is greater than the roughness of the p-SiC layers after the deposition of each respective layer, in order to ensure continuity of the separating layer over all of the interface between two successive p-SiC layers.

Typically, during the deposition of a plurality of superposed layers, the roughness increases successively with the number of layers deposited, due to the fact that the roughness of each lower layer has an influence on the roughness of the subsequently deposited layers.

For this reason, during the deposition of several successive p-SiC layers, the thickness of the separating layers can advantageously be increased with the number of depositions and the distance of each layer from the temporary support substrate. This makes it possible to compensate for the increase in the roughness and to obtain a relatively smooth surface for the layers deposited at the end of the process.

It is also possible to increase the thickness of the p-SiC layers over the course of the depositions. Preferably, the thickness of each layer corresponds to the thickness of the substrate to be fabricated plus the total variation in the thickness at the level of the layer arranged directly below the layer. This makes it possible firstly to compensate for the increase in the roughness. Moreover, the fabrication of thicker layers in the rougher zones at the end of deposition makes it possible to carry out more substantial polishing after separating the layers in order to smooth the p-SiC substrates obtained.

Thus, starting from a thickness of the first p-SiC layer of around 360 μm for a substrate with a diameter of 150 mm, the final p-SiC layer may have a thickness of up to 900 μm, and preferably of around 500 μm. Starting from a thickness of the first p-SiC layer of around 510 μm for a substrate with a diameter of 200 mm, the final p-SiC layer may have a thickness of up to 1200 μm, and preferably of around 650 μm.

### Separation of the P-SiC Substrates

After the fabrication of the multilayer structure, steps of separating the p-SiC layers are carried out in order to form a p-SiC substrate from each respective p-SiC layer.

If the p-SiC layers and the separating layers have been deposited over the entire surface of the temporary support substrate and/or if the edge of the temporary support substrate has been covered during the deposition of the successive layers, the edge of the multilayer structure is removed. With reference to FIG. 5, the p-SiC layers and the separating layers are removed along the edge of the multilayer structure to expose the edge of each respective layer and of the temporary support substrate. The removal of material along the edge of the multilayer structure is preferably carried out by mechanical trimming. In certain cases, the removal may be carried out by laser cutting.

The temporary support substrate and the separating layers arranged between the respective p-SiC layers are then removed in order to separate the SiC layers.

The removal of the temporary support substrate is typically carried out by combustion under a stream of oxygen. The temperature during the combustion is typically between 700 and 1100° C., preferably between 800° C. and 900° C.

The removal of the separation layers, for example, of carbon or of graphite, may also be carried out by combustion. Preferably, the support substrate and the separating layers are removed in a single removal step. A single removal makes it possible to increase the efficiency and thus the yield of the process and avoids additional combustion and heating steps.

The combustion temperature can be chosen according to the material and the thickness of the separating layers and can be equal to or different from the combustion temperature of the temporary support substrate. Alternatively, the separating layers may be removed by sawing, by chemical etching or by laser cutting, depending on the material, the thickness and the number of separating layers. These methods will be explained in more detail in the section relating to the separating layers.

The thickness of the separating layers can also be chosen according to the removal technique. When the separating layer is intended to be removed by chemical attack or by combustion, the thickness of the layer is preferably micrometric in order to facilitate the passage of the gases and chemicals used for the removal, and for the evacuation of the by-products obtained during the removal. This method is used, in particular, for separating layers made of carbon, of graphite, or of silicon or silicon nitride.

In embodiments including removal by liquid chemical attack, for example, for silicon or silicon nitride separating layers, the thickness of each separating layer is preferably greater than one micrometer per inch of diameter, that is to say around 25 mm of diameter.

In embodiments in which the removal is carried out by attack by a gas, for example, the combustion of carbon and/or graphite, the thickness of each separating layer is preferably greater than 0.1 micrometer per inch of diameter, that is to say per approximately 25 mm of diameter.

In certain embodiments, the removal of the support substrate is carried out in a separate step from the removal of the separating layers. For example, the removal of the temporary support substrate may be carried out at a different temperature of by a different type of process compared to the removal of the separating layers. In particular, the temporary support substrate can be removed before removing the separating layers. This subsequently makes it possible to simultaneously treat the two multilayer structures initially deposited on the two faces of the temporary support substrate.

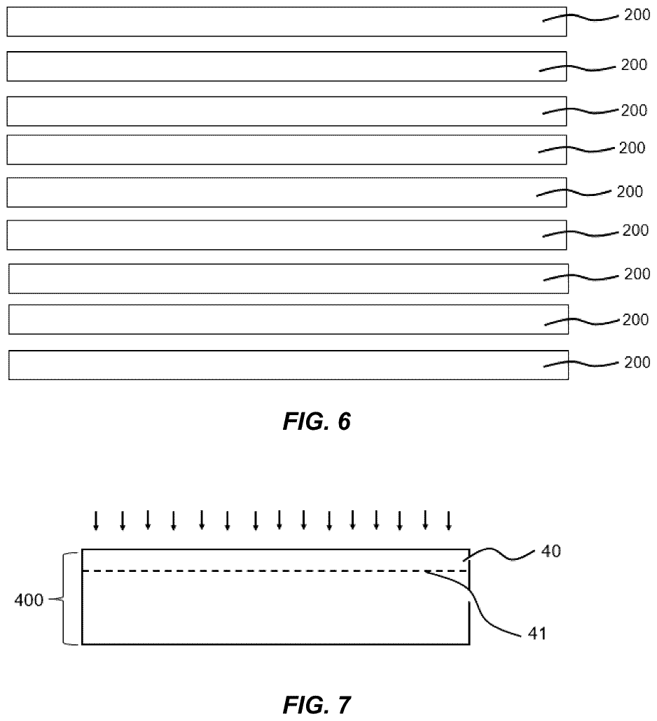

With reference to FIG. 6, the p-SiC layers are separated by the removal step and form independent p-SiC substrates 200. It is now possible to carry out finalization steps such as grinding of the p-SiC substrates 200, in particular, for adjusting the thickness of each layer to the target thickness before polishing, polishing of the substrates, heat treatments and/or surface treatments.

Deposition of the multilayer structure and the subsequent removal of the temporary support substrate thus makes it possible to simultaneously fabricate a plurality of p-SiC substrates. This process provides a higher yield than that of the fabrication of individual p-SiC substrates and makes it possible to save fabrication time and energy and to simplify the process.

The p-SiC substrates can subsequently be used as base substrate for the fabrication of substrates for electronic components.

### Separating Layers

The separating layers are made of a material that can be easily removed in a later step of the process. Preferably, the material of the separating layers may be deposited in the same chamber in which the deposition of the p-SiC layers is carried out. For example, the separating layers may be deposited by a CVD process.

The separating layers are made of a material that has a surface structure close to the crystal structure of the p-SiC in order to facilitate the deposition of other p-SiC layers after the deposition of each separating layer. The coefficient of thermal expansion of the separating layers is close to the expansion coefficient of the p-SiC in order to avoid stresses at the interfaces during all of the steps of the process that are carried out at high temperature. Advantageously, the Young's modulus of the material of the separating layers is lower than the Young's modulus of the p-SiC. For example, the separating layers may be made of carbon, of graphite, of silicon or of silicon nitride (Si₃N₄). These materials also enable a good hold at each interface between a separating layer and a p-SiC layer. This hold facilitates the handling of the multilayer structure during the steps between the deposition and the detachment of the p-SiC layers.

As described above, the thickness of the separating layers can be increased with the number of depositions and the distance of each layer from the temporary support substrate. This makes it possible to compensate for the increase in the roughness and to obtain a relatively smooth surface for the outer layers.

The thickness of the separating layers is additionally chosen such that they can easily be removed during the separation of the p-SiC layers. The thickness also depends on the material of the separating layer, on the size of the surface of the substrate, and on the removal method used. In certain cases, the thickness of the separating layer is a few nanometers. In other embodiments, it is thicker and may reach values of up to 50 μm.

The removal technique is also chosen according to the material and the thickness of the separating layers.

Illustratively and in a non-limiting manner, a separating layer made of carbon or graphite with a thickness of a few um can easily be removed by combustion at the same time as or successively to the temporary support substrate.

In the case of separating layers having a thickness of a few tens of um, the separation can be carried out by wire sawing. A separating layer made of carbon or graphite is much easier to saw than a bulk substrate made of p-SiC. Residues of the separating layer can be removed by complete or partial combustion, and/or grinding.

Depending on the doping of the p-SiC layers, laser cutting may also be envisaged. For example, a laser can be chosen having a wavelength at which the separating layers are opaque while the p-SiC layers are transparent, and thus remove only the separating layers by irradiation with such a laser.

In the case of separating layers made of silicon, thicknesses can be envisaged of, for example, between a few tens of nanometers up to around 1 μm. To remove separating layers made of silicon, the multilayer structure can be placed into a bath of tetramethylammonium hydroxide (TMAH) or tetraethylammonium hydroxide (TEAH) in order to dissolve the silicon. This step is preferably carried out after removal of the temporary support substrate by combustion. When the separating layers are made of silicon, it is preferable to limit the temperature of the CVD steps to a temperature lower than the melting point of silicon, that is 1414° C.

In other embodiments, the separating layers may be made of silicon nitride (SiN). In this case, the thickness of the separating layers is preferably between a few tens of nanometers and around 1 μm. To remove separating layers made of silicon nitride, the multilayer structure can be placed into a bath of phosphoric acid H₃PO₄ in order to dissolve the SiN and separate the p-SiC substrates. This step is preferably carried out after removal of the temporary support substrate by combustion.

Separating layers made of carbon, graphite or silicon have the advantage that these materials are already present in a CVD deposition chamber in which the silicon carbide layers are deposited. Any additional element in such a chamber is therefore avoided, thus limiting the contamination of the deposition chamber and the substrates to be fabricated. When p-SiC layers are doped with nitrogen, this element must also be present in the deposition chamber. In this case, the advantage of avoiding contamination also applies to the silicon nitride separating layers.

### Use of the P-SiC Substrates

With reference to FIGS. 7 to 9, the p-SiC substrates can be used for the fabrication of substrates for forming electronic components. Such substrates comprise at their surface a layer of a monocrystalline material such as monocrystalline silicon carbide (m-SiC), gallium nitride (GaN), gallium oxide (Ga₂O₃) or diamond.

After smoothing the front face of a p-SiC substrate fabricated by the process described above, additional steps of preparing the surface for the transfer of a monocrystalline layer may optionally be carried out. A layer of a monocrystalline material is then transferred to the front face of the p-SiC substrate.

To this end, a donor substrate 400 made of the monocrystalline material is provided. With reference to FIG. 7, as shown schematically by the arrows, implantation of ionic species into the donor substrate 400 is performed. The ionic species are, for example, hydrogen and/or helium. A weakened zone 41 defining a monocrystalline layer 40 to be transferred is thus created.

With reference to FIG. 8, the donor substrate 400 thus implanted is bonded to the p-SiC substrate 200. The bonding can be achieved by direct contacting or via one or more layers, for example, made of an oxide such as silicon dioxide, metals, for example, titanium or tungsten, and/or semiconductors or metalloids, for example, amorphous or crystalline silicon, SiC. In any case, activation of one or both surfaces, in particular, by plasma or ion bombardment, may be provided for in order to create dangling bonds before contacting the surfaces to be bonded.

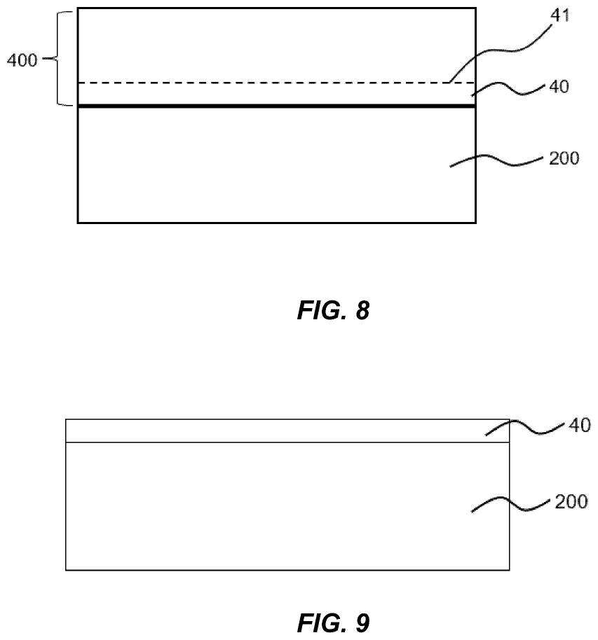

With reference to FIG. 9, the donor substrate 400 is detached along the weakened zone 41, resulting in the transfer of the monocrystalline layer 40 to the p-SiC base substrate 200. The detachment may be initiated by way of a heat treatment. A finishing treatment may then be performed on the transferred layer, so as to rectify defects linked to the implantation and to smooth the free surface of the layer.

1. A method of fabricating a plurality of polycrystalline silicon carbide substrates, comprising:
forming a multilayer structure by alternating deposition of a plurality of polycrystalline silicon carbide layers and a plurality of separating layers on at least one face of a temporary support substrate; and
eetaching each polycrystalline silicon carbide layer from the multilayer structure by removing the temporary substrate and each separating layer to form a respective polycrystalline silicon carbide substrate

2. The method of claim 1, wherein the deposition of each respective polycrystalline silicon carbide layer and of each respective separating layer is effected simultaneously over an entire outer surface of the temporary support substrate and/or of a respective underlying layer.

3. The method of claim 2, further comprising removing edges of the multilayer structure after deposition of a final polycrystalline silicon carbide layer, so as to expose an edge of the temporary support substrate.

4. The method of claim 1, wherein the temporary support substrate is made of graphite.

5. The method of claim 1, wherein each separating layer is made of carbon, graphite, silicon or silicon nitride.

6. The method of claim 5, wherein the removing the temporary support substrate is carried out by combustion under a stream of oxygen at a temperature of between 700 and 1100° C.

7. The method of claim 5, wherein the removing of each separating layer is carried out by combustion.

8. The method of claim 4, wherein the removing each separating layer is carried out by sawing or chemical etching or laser cutting.

9. The method of claim 1, wherein a thickness of the temporary support substrate is between 1 and 15 mm.

10. The method of claim 1, wherein a thickness of each polycrystalline silicon carbide layer is between 300 and 1200 μm.

11. The method of claim 1, wherein a thickness of each separating layer is between 1 and 50 μm.

12. The method of claim 1, wherein a thickness of each separating layer is between 1 and 500 nm.

13. The method of claim 1, wherein a thickness of each separating layer increases with a distance from the temporary support substrate.

14. A method of fabricating a plurality of substrates comprising a polycrystalline silicon carbide base substrate and a layer of a monocrystalline material, the process comprising in succession:
fabricating each polycrystalline silicon carbide substrate using a method according to claim 1;
smoothing a front face of each polycrystalline silicon carbide base substrate; and
transferring a layer of a monocrystalline material to the front face of each polycrystalline silicon carbide base substrate.

15. The method of claim 14, wherein transferring the monocrystalline material layer comprises:
forming a weakened zone by implanting atomic species into a donor substrate made of a monocrystalline material, to delimit a monocrystalline material layer to be transferred;
bonding the donor substrate to the front face of the base substrate; and
detaching the donor substrate along the weakened zone to transfer the layer of the monocrystalline material to the base substrate.

16. An intermediate substrate, comprising:
a temporary support substrate; and
an alternating stack of a plurality of polycrystalline silicon carbide layers and separating layers on at least one face of the temporary substrate.

17. The intermediate substrate of claim 16, wherein the temporary support substrate is made of graphite.

18. The intermediate substrate of claim 16, wherein each separating layer is made of carbon, graphite, silicon or silicon nitride.

19. The intermediate substrate of claim 16, wherein a thickness of each separating layer increases with a distance from the temporary support substrate.

20. The method of claim 6, wherein the removing the temporary support substrate is carried out by combustion under a stream of oxygen at a temperature of between 800 and 900° C.
